(19) United States
(12) Patent Application Publication
(10) Pub. No.: US 2025/0386525 A1
(43) Pub. Date: Dec. 18, 2025

(54) CAPACITOR, METHOD OF MANUFACTURING THE CAPACITOR, ELECTRONIC DEVICE INCLUDING THE CAPACITOR, AND METHOD OF MANUFACTURING THE ELECTRONIC DEVICE

(71) Applicants: SK hynix Inc., Icheon-si (KR); KOREA ADVANCED INSTITUTE OF SCIENCE AND TECHNOLOGY, Daejeon (KR)

(72) Inventors: Jeongyeop LEE, Daejeon (KR); Woo Young Park, Daejeon (KR); Jiwon Moon, Daejeon (KR); Kivin Im, Daejeon (KR); Byung Jin Cho, Daejeon (KR); Seongho Kim, Daejeon (KR)

(21) Appl. No.: 19/234,732

(22) Filed: Jun. 11, 2025

(30) Foreign Application Priority Data
Jun. 14, 2024 (KR) 10-2024-0077369

(51) Int. Cl. H10D 1/68; H10B 12/00; H10D 1/00

(52) U.S. Cl. CPC H10D 1/68; H10B 12/033; H10B 12/315; H10D 1/041; H10D 1/716

(57) ABSTRACT

Disclosed are a device and method for an electronic device including a capacitor. The capacitor may include a first electrode; a second electrode disposed spaced apart from the first electrode; and a dielectric layer disposed between the first electrode and the second electrode, wherein the dielectric layer comprises: a first hafnium zirconium oxide layer region disposed in contact with or adjacent to the first electrode, and being doped with a first doping material, and a second hafnium zirconium oxide layer region disposed in contact with or adjacent to the second electrode, and being doped with a second doping material different from the first doping material; and an interlayer region disposed between the first and second hafnium zirconium oxide layer regions.

### CROSS-REFERENCES TO RELATED APPLICATION

The present application claims, under 35 U.S.C. § 119(a), the benefit of Korean Patent Application No. 10-2024-0077369, filed on Jun. 14, 2024 which is herein incorporated by reference in its entirety.

### BACKGROUND

### 1. Field

Embodiments of the present disclosure relates to electronic elements, devices including such elements, and methods of manufacturing the same, and more particularly to capacitors, methods of manufacturing the capacitors, electronic devices including the capacitors, and methods of manufacturing the electronic devices.

### 2. Description of the Related Art

Advancements in semiconductor manufacturing processes are driving the continued scaling of integrated circuits. In dynamic random access memory (DRAM) that is a representative semiconductor device, an area occupied by a capacitor, which is the fundamental element of a memory cell, is gradually decreasing. Despite the reduction in size, a certain level of capacitance must be maintained to endure reliable performance, longevity, and error tolerance during device operation. Accordingly, there is a growing need for the development of high-dielectric constant materials (i.e., high-k materials) and ongoing improvements in capacitor performance to maintain the required capacitance of capacitors.

Hafnium zirconium oxide has emerged as a promising candidate for next generation high-k materials. However, as the physical thickness of hafnium zirconium oxide thin films decreases, issues such as increased leakage current and reduced durability arise. Additionally, the energy required for crystallization increases due to higher surface energy associated with smaller grain size, making crystallization more difficult. In addition, oxygen deficiencies (i.e., oxygen vacancies) in the thin films can lead to additional leakage current, thereby compromising the durability and reliability of electronic devices incorporating such thin films.

### SUMMARY

An objective of the present disclosure is to provide a capacitor including a dielectric layer having a high dielectric constant and improved leakage current characteristics, capable of achieving a reduced equivalent oxide thickness (EOT), as well as a method for manufacturing the same.

Furthermore, an objective of the present disclosure is to provide a capacitor and a method of manufacturing the same, wherein a dielectric constant is increased and durability is enhanced by controlling the crystallinity of a dielectric layer of the capacitor.

Furthermore, an objective of the present disclosure is to provide an electronic device (e.g., a memory device) including the afore-mentioned capacitor, as well as a method of manufacturing the same.

It should be understood that the objectives of the present disclosure are not limited to the objectives mentioned above, and additional objectives will be apparent to those skilled in art from the following detailed description.

According to one embodiment of the present disclosure, a capacitor comprising: a first electrode; a second electrode spaced apart from the first electrode; and a dielectric layer disposed between the first electrode and the second electrode, the dielectric layer comprising: a first hafnium zirconium oxide layer region in contact with or adjacent to the first electrode and the first hafnium zirconium oxide layer region being doped with a first doping material; and a second hafnium zirconium oxide layer region in contact with or adjacent to the second electrode and the second hafnium zirconium oxide layer region doped with a second doping material different from the first doping material; and an interlayer region disposed between the first and second hafnium zirconium oxide layer regions.

The first doping material may comprise an element that induces compressive stress in the first hafnium zirconium oxide layer region, and the second doping material may comprise an element that induces tensile stress in the second hafnium zirconium oxide layer region.

The first doping material may comprise an element having a smaller atomic size than Hf and Zr, and the second doping material may comprise an element having a larger atomic size than Hf and Zr.

The first doping material may comprise Ta, Ti, or a combination thereof, and the second doping material may comprise La, Y, or a combination thereof.

The proportion of tetragonal phases in the dielectric layer may be about 20% or more.

The interlayer region may comprise an oxide containing at least one element selected from the group consisting of Al, Y, La, Ta, Ca, Si, Zr, Hf, and Ti.

The capacitor may further comprise: a first interfacial layer disposed between the first electrode and the first hafnium zirconium oxide layer region; and a second interfacial layer disposed between the second electrode and the second hafnium zirconium oxide layer region.

At least one of the first and second interfacial layers may comprise an oxide containing of In, Ga, Zn, Ti, Al, Sn, Y, Ca, Ba, and Sr or comprise InGaZnO.

According to another embodiment of the present disclosure, a capacitor comprising: a first electrode; a second electrode disposed spaced apart from the first electrode; and a dielectric layer disposed between the first electrode and the second electrode, the dielectric layer comprising: a first hafnium zirconium oxide layer region having a compressively strained structure, in contact with or adjacent to the first electrode; and a second hafnium zirconium oxide layer region having a tensile strained structure, in contact with or adjacent to the second electrode; and an interlayer region disposed between the first and second hafnium zirconium oxide layer regions.

According to another embodiment of the present disclosure, there is provided a memory element comprising the afore-mentioned capacitor as a data storage member.

The memory device may be a dynamic random access memory (DRAM).

According to another embodiment of the present disclosure, a method of manufacturing a capacitor, comprising: preparing a first electrode; forming a dielectric layer on the first electrode; forming a second electrode on the dielectric layer; and heat treating a laminated structure comprising the first electrode, the dielectric layer and the second electrode, the dielectric layer comprises a first hafnium zirconium oxide layer region in contact with or adjacent to the first electrode and doped with a first doping material, a second hafnium zirconium oxide layer region in contact with or adjacent to the second electrode and doped with a second doping material different from the first doping material, and an interlayer region disposed between the first and second hafnium zirconium oxide layer regions.

The dielectric layer may be formed using an atomic layer deposition (ALD) process.

The first doping material may comprise an element that induces compressive stress in the first hafnium zirconium oxide layer region, and the second doping material may comprise an element that induces tensile stress in the second hafnium zirconium oxide layer region.

The first doping material may comprise an element having a smaller atomic size than Hf and Zr, and the second doping material may comprise an element having a larger atomic size than Hf and Zr.

The first doping material may comprise Ta, Ti, or a combination thereof, and the second doping material may comprise La, Y, or a combination thereof.

The proportion of tetragonal phases in the dielectric layer may be equal to or greater than 20%.

The interlayer region may comprise an oxide containing at least one element selected from the group consisting of Al, Y, La, Ta, Ca, Si, Zr, Hf, and Ti.

The method of manufacturing the capacitor may further comprise at least one of the steps of forming a first interfacial layer disposed between the first electrode and the first hafnium zirconium oxide layer region; and forming a second interfacial layer disposed between the second electrode and the second hafnium zirconium oxide layer region.

At least one of the first and second interfacial layers may comprise an oxide containing at least one element selected from the group consisting of In, Ga, Zn, Ti, Al, Sn, Y, Ca, Ba, and Sr or comprises InGaZnO.

The heat treatment may be performed at a temperature of about 400 to 700° C.

According to embodiments of the present disclosure, a capacitor may be implemented that includes a dielectric layer capable of having a thin equivalent oxide thickness (EOT) while maintaining a high dielectric constant and exhibiting improved leakage current characteristics. Further, according to embodiments of the present disclosure, by controlling the crystallinity of a dielectric layer, a capacitor may demonstrate enhanced dielectric performance and improved durability. Further, according to embodiments of the present disclosure, a capacitor including a hafnium zirconium oxide layer may reduce leakage current while enhancing both durability and long-term reliability.

In particular, according to some embodiments of the present disclosure, the dielectric properties and durability may be improved and a thin equivalent oxide thickness (EOT) may be obtained by varying the doping materials in the lower and upper regions of the dielectric layer to induce crystallinity changes across the entire dielectric layer. According to embodiments of the present disclosure, a high dielectric constant and excellent electrical properties may be obtained by creating a phase transition region (i.e., a morphotropic phase boundary (MPB) or a similar state) in which anti-ferroelectric tetragonal crystalline grains coexist with ferroelectric orthorhombic crystalline grains in hafnium zirconium oxide.

The capacitors according to embodiments of the present disclosure may be usefully applied to electronic devices, for example, memory devices such as DRAM, where they may contribute to enhanced integration and improved device performance.

However, the effects of the present disclosure are not limited to the above effects, and may be extended in various ways without departing from the spirit and scope of the present disclosure.

### BRIEF DESCRIPTION OF THE DRAWINGS

FIG. 1 illustrates a cross-sectional view of a capacitor according to an embodiment of the present disclosure.

FIG. 2 illustrates the stress distribution in different areas of a capacitor according to an embodiment of the present disclosure.

FIG. 3 illustrates a cross-sectional view of a capacitor according to another embodiment of the present disclosure.

FIG. 4 illustrates zonal stresses that may be present in a capacitor according to an embodiment of the present disclosure.

FIGS. 5A through 5D illustrate a method of manufacturing a capacitor according to an embodiment of the present disclosure.

FIGS. 6A through 6D illustrate a method of manufacturing a capacitor according to another embodiment of the present disclosure.

FIG. 7 illustrates a method of manufacturing a capacitor according to an embodiment of the present disclosure, as well as a capacitor manufactured by the method.

FIG. 8 illustrates a cross-sectional view of a capacitor according to a comparative example.

FIG. 9 is a graph showing results of measuring crystal structures of dielectric layers (or thin films) of capacitors according to an embodiment and a comparative example of the present disclosure.

FIGS. 10A and FIG. 10B show transmission electron microscope (TEM) images of crystal structures of dielectric layers (or thin films) of capacitors according to an embodiment and a comparative example of the present disclosure.

FIG. 11 is a graph showing the change in equivalent oxide thickness (EOT) as a function of annealing (heat treatment) temperature conditions of dielectric layers according to an embodiments and a comparative example of the present disclosure.

FIG. 12 is a graph showing the variation in ΔPᵣ (remanent polarization) with increasing operating cycles of dielectric layers according to an embodiment and a comparative example of the present disclosure.

FIG. 13 is a graph showing P-E (polarization-electric field) characteristics of a dielectric layer according to an embodiment of the present disclosure.

FIG. 14 illustrates a morphotropic phase boundary (MPB) state that a dielectric layer of a capacitor according to an embodiment of the present disclosure may exhibit.

FIG. 15 illustrates an exemplary configuration of a DRAM device including a capacitor according to an embodiment of the present disclosure.

### DETAILED DESCRIPTION

Embodiments of the present disclosure will now be described in detail with reference to the accompanying drawings.

The embodiments of the disclosure described below are provided for the purpose of more clearly illustrating the disclosure to those having ordinary skill in the art, and the scope of the disclosure is not intended to be limited by the following embodiments, which may be modified in various other ways.

The terms used in this specification are intended to describe specific embodiments and are not intended to limit the disclosure. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

Further, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present disclosure will now be described in detail with reference to the accompanying drawings. The sizes or thicknesses of the areas or parts shown in the accompanying drawings may be somewhat exaggerated for clarity and ease of description. Throughout the detailed description, like reference numerals designate like components.

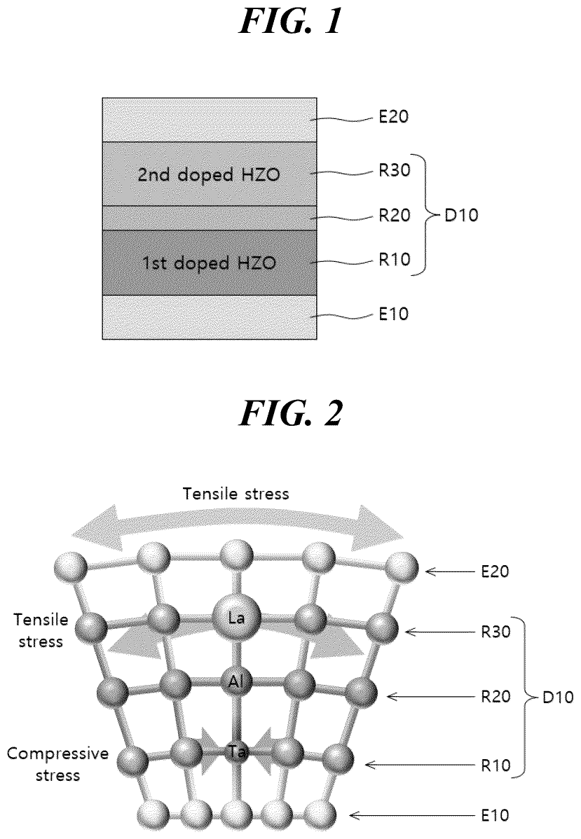

FIG. 1 illustrates a cross-sectional view of a capacitor according to an embodiment of the present disclosure.

Referring to FIG. 1, the capacitor may include a first electrode E10, a second electrode E20 spaced apart from the first electrode E10, and a dielectric layer D10 disposed between the first electrode E10 and the second electrode E20 in a stacking direction. The dielectric layer D10 may include a first hafnium zirconium oxide layer region R10 disposed adjacent to the first electrode E10, a second hafnium zirconium oxide layer region R30 disposed adjacent to the second electrode E20, and an interlayer region R20 disposed between the first and second hafnium zirconium oxide layer regions R10 and R30 in the stacking direction.

The first hafnium zirconium oxide layer region R10 may be a region doped with a first doping material. The second hafnium zirconium oxide layer region R30 may be a region doped with a second doping material different from the first doping material. In one example, the first electrode E10 may be a lower electrode and the second electrode E20 may be a higher electrode. The first hafnium zirconium oxide layer region R10, the interlayer region R20, the second hafnium zirconium oxide layer region R30, and the second electrode E20 may be sequentially disposed on the first electrode E10 in the stacking direction.

The hafnium zirconium oxide in the first and second hafnium zirconium oxide layer regions R10 and R30 may be a high-k material. The hafnium zirconium oxide may be represented by HfZr oxide or HfZrO, or more generally by the formula HfₓZr_{y}O_{z}. Here, x may satisfy 0<x<1, y may satisfy 0<y<1, and z may satisfy 1.5<z≤2. For example, the hafnium zirconium oxide may be HfₓZr₁₋ₓO₂, wherein x satisfies 0<x<1. However, the composition ratio of HfₓZr_{y}O_{z} may vary.

The first doping material (dopant) doped into the first hafnium zirconium oxide layer region R10 may include an element that induces compressive stress within the first hafnium zirconium oxide layer region R10. The first dopant may be an element having an atomic size smaller than those of Hf and Zr. For example, the first doping material may include at least one element selected from the group consisting of Ta, Ti, and the like. As a result of doping the first hafnium zirconium oxide layer region R10 with the first doping material, the first hafnium zirconium oxide layer region R10 may exhibit a compressively strained structure.

The second doping material (dopant) doped into the second hafnium zirconium oxide layer region R30 may include an element that induces tensile stress within the second hafnium zirconium oxide layer region R30. The second dopant may be an element having an atomic size larger than those of Hf and Zr. For example, the second doping material may include at least one element selected from the group consisting of La, Y, and the like. As a result of doping the second hafnium zirconium oxide layer region R30 with the second doping material, the second hafnium zirconium oxide layer region R30 may exhibit a tensile strained structure.

By doping the first and second hafnium zirconium oxide layer regions R10 and R30 with different predetermined doping materials, the first hafnium zirconium oxide layer region R10 may undergo compressive deformation and the second hafnium zirconium oxide layer region R30 may undergo tensile deformation. Thus, the crystal properties of the dielectric layer D10 may be changed. When the first hafnium zirconium oxide layer region R10 is doped with an element having an atomic size smaller than those of Hf and Zr, and the second hafnium zirconium oxide layer region R30 is doped with an element having an atomic size larger than those of Hf and Zr, the resulting atomic size mismatch may induce stress in the first and second hafnium zirconium oxide layer regions R10 and R30. This stress may allow for control over the crystallinity of the dielectric layer D10.

If asymmetric structural doping is performed, in which the first and second hafnium zirconium oxide layer regions R10 and R30 are doped with different materials, the stress may be enhanced, leading to more pronounced changes in crystallinity. In this regard, the proportion of tetragonal phases in the dielectric layer D10 may increase. In other words, the tetragonal crystallinity in the dielectric layer D10 may increase. For example, the proportion of tetragonal phases in the dielectric layer D10 may be about 20% or more. As a non-limiting example, the proportion of tetragonal phases in the dielectric layer D10 may be greater than about 20% and less than or equal to about 50%. As the proportion of tetragonal phases in the dielectric layer D10 increases, the dielectric permittivity of the dielectric layer D10 may increase, the equivalent oxide film thickness (EOT) may decrease, and the operational durability may be enhanced.

Furthermore, as the proportion of tetragonal phases in the dielectric layer D10 increases, the anti-ferroelectric properties of the dielectric layer D10 may be enhanced. In hafnium zirconium oxide, the tetragonal phase may be semi-ferroelectric, whereas the orthorhombic phase may be ferroelectric. When the proportion of tetragonal phase in the dielectric layer D10 is sufficiently increased, the semi-ferroelectric characteristics may become more prominent, resulting in a high dielectric constant near 0 V and improved operational durability. The dielectric layer D10 may reach or have a state similar to a phase transition region (i.e., a morphotropic phase boundary (MPB)), in which tetragonal and orthorhombic grains coexist. In this state, the dielectric layer D10 may exhibit a high dielectric constant and excellent electrical performance.

The interlayer region R20 may serve to reduce the leakage current of the dielectric layer D10 and further improve its durability. The interlayer region R20 may include an element having a high oxidation formation energy in the negative direction. The interlayer region R20 may include an element having a higher oxidation formation energy in the negative direction than Hf and Zr. The oxidation formation energy may also be referred to as oxide formation energy. Further, the interlayer region R20 may have a larger energy bandgap than the HfZr oxide. In particular, the interlayer region R20 may have a larger energy bandgap than at least one of the first and second hafnium zirconium oxide layer regions R10 and R30. Due to its higher oxidation formation energy and larger bandgap, the interlayer region R20 may exhibit a strong resistance to oxygen loss, which may be beneficial for reducing leakage current and improving the overall reliability and durability of the dielectric layer D10.

According to one embodiment, the interlayer region R20 may include an oxide containing at least one of Al, Y, La, Ta, Ca, Si, Zr, Hf, or Ti. The interlayer region R20 may be a hafnium zirconium oxide layer region doped with a predetermined element. The predetermined element may include one or more of Al, Y, La, Ta, Ca, Si, Zr, Hf, and Ti. According to a non-limiting example, the interlayer region R20 may be an Al-doped hafnium zirconium oxide layer region. Here, the hafnium zirconium oxide in the hafnium zirconium oxide layer region may be the same as, or similar to, the hafnium zirconium oxide described for the first and second hafnium zirconium oxide layer regions R10 and R30. In some cases, however, the interlayer region R20 may include at least one of Al oxide, Y oxide, La oxide, Ta oxide, Ca oxide, Si oxide, Zr oxide, Hf oxide, or Ti oxide. As a non-limiting example, the interlayer region R20 may include or consist of an Al oxide (e.g., Al₂O₃).

The first electrode E10 may include, for example, at least one of TiN, Pt, Ru, RuO₂, Ir, IrO₂, W, or WN. For example, the first electrode E10 may include TiN or may be formed from TiN. However, the material of the first electrode E10 is not limited to these examples and may vary depending on the specific implementation.

Similar to the first electrode E10, the second electrode E20 may include at least one of TiN, Pt, Ru, RuO₂, Ir, IrO₂, W, or WN, by way of example. However, the material of the second electrode E20 is not limited to these examples and may vary depending on the specific implementation. Furthermore, each of the first electrode E10 and the second electrode E20 may have either a monolayer structure or a multilayer structure. Additionally, each of the first electrode E10 and the second electrode E20 may further include impurities such as Si, C, Cl, or the like.

The first hafnium zirconium oxide layer region R10 may have a thickness of about 1 to 20 nm. Similarly, the second hafnium zirconium oxide layer region R30 may have a thickness of about 1 to 20 nm. The intermediate layer region R20 may have a thickness of about 0.1 to 3 nm. The dielectric layer D10 may have a thickness of about 2 to 20 nm.

FIG. 2 illustrates zonal stresses that may be present in a capacitor, according to an embodiment of the present disclosure.

Referring to FIG. 2, a capacitor according to an embodiment may have a stacked structure as described with reference to FIG. 1. The reference numerals in FIG. 2 may be the same as those used in FIG. 1. FIG. 2 schematically illustrates an example in which the first hafnium zirconium oxide layer region R10 is doped with Ta, the second hafnium zirconium oxide layer region R30 is doped with La, and the interlayer region R20 includes Al. A compressive stress may be applied to the first hafnium zirconium oxide layer region R10, and a tensile stress may be applied to the second hafnium zirconium oxide layer region R30. In addition, a tensile stress may be applied to the second electrode E20, which abuts or is adjacent to the second hafnium zirconium oxide layer region R30.

In a comparative example, a capacitor may have a laminated structure of TiN/ZrO₂/Al₂O₃/ZrO₂/TiN. In this structure, a dielectric film consists of a ZrO₂/Al₂O₃/ZrO₂ stack, with TiN layers at both ends serving as electrodes. For this dielectric film, achieving crystallization into a specific phase is challenging due to the reduced grain size resulting from the thin film thickness and the relatively low post metallization annealing (PMA) temperature, which is below 600° C. These factors limit the ability to secure a high dielectric constant.

The capacitor according to the embodiment of the present disclosure may use the first and second hafnium zirconium oxide layer regions R10 and R30, which are doped with different predetermined doping materials to induce a change in the crystallinity of a thin film. For example, if the first hafnium zirconium oxide layer region R10 is doped with an element having an atomic size smaller than those of Hf and Zr, and the second hafnium zirconium oxide layer region R30 is doped with an element having an atomic size larger than those of Hf and Zr, the resulting atomic size mismatch may induce stress in the first and second hafnium zirconium oxide layer regions R10 and R30, thereby enabling control over the crystallinity of the thin film. When asymmetric structure doping is performed, in which the first and second hafnium zirconium oxide layer regions R10 and R30 are doped with different doping materials, an apparent change in crystallinity may be induced by enhanced stress. The thin film corresponding to the dielectric layer D10 may bend in a certain direction due to the applied stress. As a result, the dielectric constant of the dielectric layer D10 may increase, the equivalent oxide film thickness (EOT) may decrease, and the operational durability may be improved. According to embodiments, stress engineering may enhance crystallinity, increase a dielectric constant, reduce leakage current, and improve durability.

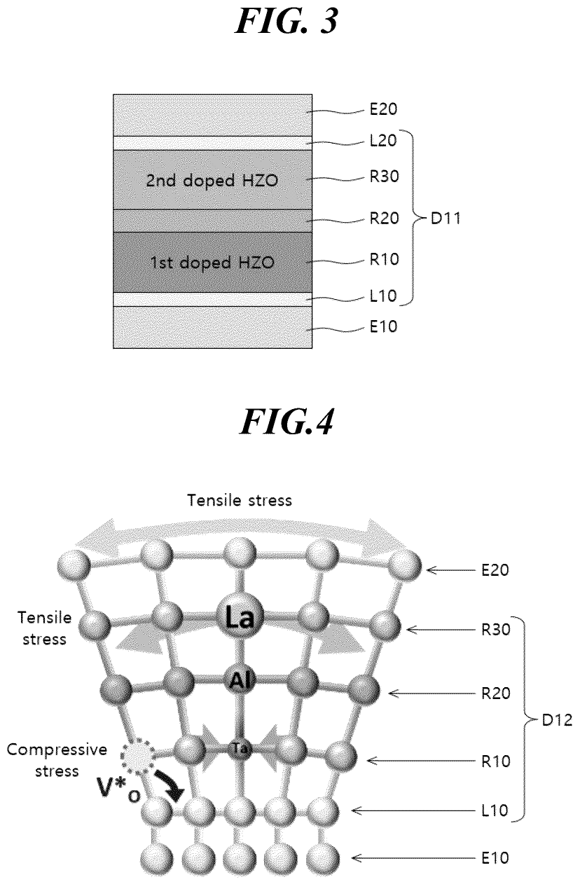

FIG. 3 illustrates a cross-sectional view of a capacitor according to another embodiment of the present disclosure.

Referring to FIG. 3, the capacitor may further include one or more of a first interfacial layer L10 disposed between a first electrode E10 and a first hafnium zirconium oxide layer region R10 and a second interfacial layer L20 disposed between a second electrode E20 and a second hafnium zirconium oxide layer region R30. The first interfacial layer L10 may be referred to as a first insertion layer, and the second interfacial layer L20 may be referred to as a second insertion layer. The first and second interfacial layers L10 and L20 may be dielectric material layers. Therefore, a dielectric layer D11 of the capacitor may include the first interfacial layer L10, the first hafnium zirconium oxide layer region R10, the interlayer region R20, the second hafnium zirconium oxide layer region R30, and the second interfacial layer L20. The rest of the configuration may be the same as, or similar to, that described in FIG. 1, except that the first and second interfacial layers L10 and L20 are further provided.

The first and second interfacial layers L10 and L20 may include elements (e.g., metallic elements) having a lower oxygen affinity than Hf and Zr. The first interfacial layer L10 may serve to supply oxygen to at least the first hafnium zirconium oxide layer region R10, acting as an oxygen donor. The second interfacial layer L20 may serve to supply oxygen to at least the second hafnium zirconium oxide layer region R30, also acting as an oxygen donor. In the event that the first and second hafnium zirconium oxide layer regions R10 and R30 lose some oxygen during the capacitor's operation cycle, the first and second interfacial layers L10 and L20 may function as oxygen donors. Furthermore, the first and second interfacial layers L10 and L20 may act as barriers to prevent penetration of oxygen vacancies. Accordingly, the first and second interfacial layers L10 and L20 may contribute to enhanced operational durability and reliability of the capacitor.

According to one embodiment, at least one of the first and second interfacial layers L10 and L20 may include an oxide containing at least one of In, Ga, Zn, Ti, Al, Sn, Y, Ca, Ba, or Sr, or InGaZnO. At least one of the first and second interfacial layers L10 and L20 may be an oxide layer. As a non-limiting example, at least one of the first and second interfacial layers L10 and L20 may be, or may include, an indium gallium zinc oxide layer. The indium gallium zinc oxide layer may be represented by an InGaZn oxide layer or an InGaZnO layer (or thin film). The indium gallium zinc oxide layer may be represented as an InₐGa_{b}Zn_{c}O_{d} layer (or thin film), where the composition parameters may satisfy the following conditions: 0<a<1,0<b<1,0<c<1, and 1.5<d≤2. However, the composition ratio of the InₐGa_{b}Zn_{c}O_{d} layer may be varied. Furthermore, the specific materials used for the first and second interfacial layers L10 and L20 may also be varied. As a non-limiting example, the thickness of the first interfacial layer L10 may be about 0 to 3 nm, and the thickness of the second interfacial layer L20 may be about 0 to 3 nm.

In one embodiment, the proportion of tetragonal phases in the dielectric layer D11 may be greater than or equal to about 20%. As a non-limiting example, the proportion of tetragonal phases in the dielectric layer D11 may be greater than about 20% and less than or equal to about 50%. Furthermore, the proportion of tetragonal phases in the entire layered structure including the first and second hafnium zirconium oxide layer regions R10 and R30 and the interlayer region R20 may be greater than or equal to about 20%. As a non-limiting example, the proportion of tetragonal phases throughout the layer structure including the first and second hafnium zirconium oxide layer regions R10 and R30 and the interlayer region R20 may be greater than about 20% and less than or equal to about 50%.

FIG. 4 illustrates a schematic diagram of zonal stresses that may be present in a capacitor according to an embodiment of the present disclosure.

Referring to FIG. 4, the capacitor may have a laminated structure similar to that shown in FIG. 3, except that the second interfacial layer L20 is excluded. The reference numerals E10, L10, R10, R20, R30, and E20 in FIG. 4 may correspond to those described in FIG. 3. FIG. 4 schematically illustrates a case where a first hafnium zirconium oxide layer region R10 is doped with Ta, a second hafnium zirconium oxide layer region R30 is doped with La, an interlayer region R20 includes Al, and a first interfacial layer L10 is additionally applied. Here, a dielectric layer D12 may include the first interfacial layer L10, the first hafnium zirconium oxide layer region R10, the interlayer region R20, and the second hafnium zirconium oxide layer region R30. A compressive stress may be applied to the first hafnium zirconium oxide layer region R10, and a tensile stress may be applied to the second hafnium zirconium oxide layer region R30. In addition, a tensile stress may be applied to the second electrode E20, which abuts or is adjacent to the second hafnium zirconium oxide layer region R30.

When the first hafnium zirconium oxide layer region R10 or a similar region loses some oxygen during the capacitor's operation cycle, the first interfacial layer L10 may serve to supply oxygen to the first hafnium zirconium oxide layer region R10. Thus, the first interfacial layer L10 may further improve the operational durability and reliability of the capacitor. In FIG. 4, V^{*}ₒ represents an oxygen vacancy.

A method of manufacturing a capacitor according to one embodiment of the present disclosure may include preparing a first electrode, forming a dielectric layer on the first electrode, forming a second electrode on the dielectric layer, and heat treating a laminated structure including the first electrode, the dielectric layer, and the second electrode. The dielectric layer may include a first hafnium zirconium oxide layer region disposed tangentially or adjacent to the first electrode and doped with a first doping material, a second hafnium zirconium oxide layer region disposed tangentially or adjacent to the second electrode and doped with a second doping material different from the first doping material, and an interlayer region disposed between the first and second hafnium zirconium oxide layer regions in a stacking direction. The dielectric layer may be formed, for example, by an atomic layer deposition (ALD) process. The constituent material layers (or material regions) of the dielectric layer may be depositable at a temperature (or process temperature) of about 200 to 400° C., as a non-limiting example. The heat treatment may include post metallization annealing (PMA).

According to one embodiment, the first doping material may include an element that induces compressive stress in the first hafnium zirconium oxide layer region. The second doping material may include an element that induces tensile stress in the second hafnium zirconium oxide layer region. The first doping material may include an element having an atomic size smaller than those of Hf and Zr, and the second doping material may include an element having an atomic size larger than those of Hf and Zr. As a specific example, the first doping material may include at least one element selected from the group consisting of Ta, Ti, and the like, and the second doping material may include at least one element selected from the group consisting of La, Y, and the like. The proportion of tetragonal phases in the dielectric layer may be about 20% or more. The interlayer region may include an oxide containing, for example, at least one of Al, Y, La, Ta, Ca, Si, Zr, Hf, or Ti.

The method of manufacturing the capacitor may further include at least one of forming a first interfacial layer disposed between the first electrode and the first hafnium zirconium oxide layer region and forming a second interfacial layer disposed between the second electrode and the second hafnium zirconium oxide layer region. According to one embodiment, at least one of the first and second interfacial layers may include an oxide containing at least one of In, Ga, Zn, Ti, Al, Sn, Y, Ca, Ba, or Sr, or InGaZnO.

The heat treatment may be performed, for example, at a temperature in the range of about 400 to 700° C. Further, the heat treatment may be performed, for example, using rapid thermal annealing (RTA).

In addition, the structures and features of the capacitors described with reference to FIGS. 1 to 4 may be equally applicable to the method of manufacturing the capacitors.

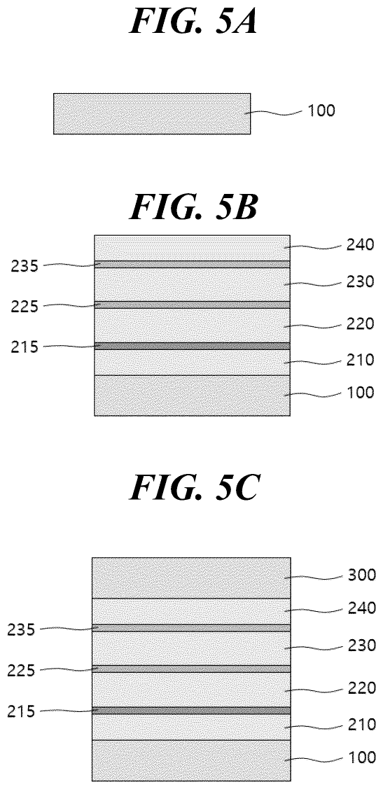

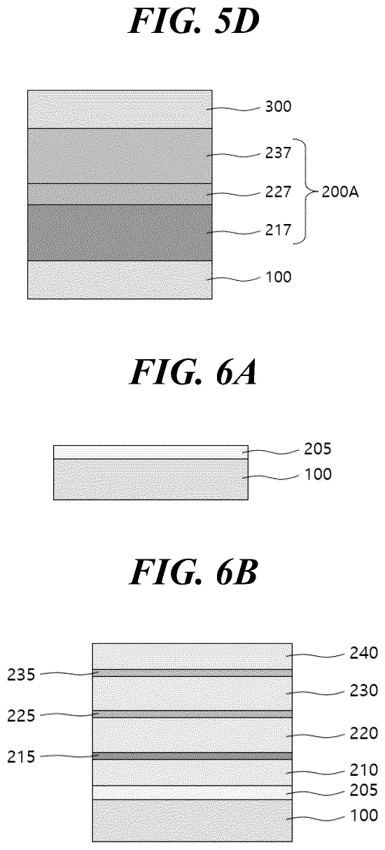

FIGS. 5A through 5D illustrate a method of manufacturing a capacitor according to an embodiment of the present disclosure.

Referring to FIG. 5A, a first electrode 100 may be provided. The first electrode 100 may include, for example, at least one of TiN, Pt, Ru, RuO₂, Ir, IrO₂, W, or WN. As a non-limiting example, the first electrode 100 may include TiN or be formed from TiN. However, the material of the first electrode 100 is not limited to the foregoing and may vary depending on the specific implementation.

The first electrode 100 may be formed, for example, by a plasma enhanced atomic layer deposition (PEALD) process. When the first electrode 100 is formed from TiN, TiCl₄ may be utilized as a titanium precursor in the PEALD process, N₂ may be utilized as a reactant gas, and H₂ may be utilized as a gas for plasma generation. However, the above process conditions for the formation of the first electrode 100 are merely exemplary and may vary. Furthermore, the method of forming the first electrode 100 is not limited to PEALD and may alternatively include processes such as physical vapor deposition (PVD) or chemical vapor deposition (CVD).

Referring to FIG. 5B, hafnium zirconium oxide layers 210, 220, 230, and 240 are deposited on the first electrode 100 using an ALD process. During the deposition of these hafnium zirconium oxide layers 210, 220, 230, and 240, a first doping material layer 215, an intermediate material layer 225, and a second doping material layer 235 may be formed therebetween. For example, the first hafnium zirconium oxide layer 210 is formed on the first electrode 100; the first doping material layer 215 is formed on the first hafnium zirconium oxide layer 210; the second hafnium zirconium oxide layer 220 is then formed thereon, followed by formation of the intermediate material layer 225. The third hafnium zirconium oxide layer 230 is subsequently formed thereon, followed by the second doping material layer 235; and finally the fourth hafnium zirconium oxide layer 240 is formed thereon.

The ALD process for forming the hafnium zirconium oxide layer may include a step 1 of supplying a precursor for the formation of the hafnium zirconium oxide layer in a chamber in which the first electrode 100 is disposed, a step 2 of purging the chamber with a purge gas, a step 3 of supplying a first reactant in the chamber, and a step 4 of purging the chamber with a purge gas. The steps 1 through 4 may be performed repeatedly to form the hafnium zirconium oxide layers 210, 220, 230, and 240.

The ALD process for forming the first doping material layer 215 may include a step 5 of supplying a precursor for the formation of the first doping material layer 215 in the chamber, a step 6 of purging the chamber with a purge gas, a step 7 of supplying a second reactant in the chamber, and a step 8 of purging the chamber with a purge gas. The steps 5 through 8 may be performed either once or repeatedly.

The ALD process for forming the intermediate material layer 225 may include a step 9 of supplying a precursor for the formation of the intermediate material layer 225 in the chamber, a step 10 of purging the chamber with a purge gas, a step 11 of supplying a third reactant in the chamber, and a step 12 of purging the chamber with a purge gas. The steps 9 through 12 may be performed either once or repeatedly. The intermediate material layer 225 may be, for example, a type of doping material layer.

The ALD process for forming the second doping material layer 235 may include a step 13 of supplying a precursor for the formation of the second doping material layer 235 in the chamber, a step 14 of purging the chamber with a purge gas, a step 15 of supplying a fourth reactant in the chamber, and a step 16 of purging the chamber with a purge gas. The steps 13 to 16 may be performed either once or repeatedly. Each of the first to fourth reactants may be an oxidizing agent.

The formation locations of the first doping material layer 215 and the second doping material layer 235 may vary and are not limited to the positions shown. In another embodiment, the first doping material layer 215 may be formed below the first hafnium zirconium oxide layer 210 in the stacking direction. In this case, a single hafnium zirconium oxide layer, rather than both the first hafnium zirconium oxide layer 210 and the second hafnium zirconium oxide layer 220, may be positioned between the first doping material layer 215 and the intermediate material layer 225. Furthermore, the second doping material layer 235 may be formed on top of the fourth hafnium zirconium oxide layer 240. In this case, a single hafnium zirconium oxide layer, rather than both the third hafnium zirconium oxide layer 230 and the fourth hafnium zirconium oxide layer 240, may be present between the second doping material layer 235 and the intermediate material layer 225.

According to one embodiment, the first doping material layer 215 may include at least one element selected from the group consisting of, for example, Ta, Ti, and the like. If the first doping material layer 215 includes Ta, it may be in the form of Ta₂O₅. The second doping material layer 235 may include at least one element selected from the group consisting of, for example, La, Y, and the like. If the second doping material layer 235 includes La, it may be in the form of La₂O₃. The intermediate material layer 225 may include, for example, at least one of Al, Y, La, Ta, Ca, Si, Zr, Hf, or Ti. When the intermediate material layer 225 includes Al, the intermediate material layer 225 may be in the form of Al₂O₃.

Referring to FIG. 5C, a second electrode 300 may be formed on the fourth hafnium zirconium oxide layer 240. The second electrode 300 may include, for example, at least one of TiN, Pt, Ru, RuO₂, Ir, IrO₂, W, or WN. As a non-limiting example, the second electrode 300 may include TiN or be formed from TiN. However, the material of the second electrode 300 is not limited to the foregoing and may vary depending on the specific implementation.

The second electrode 300 may be formed from TiN, for example, by the PEALD process. In this case, the specific method for forming the second electrode 300 may be the same as, or similar to, the method for forming the first electrode 100. The method of forming the second electrode 300 is not limited to PEALD and may be varied. The second electrode 300 may also be formed by a PVD or CVD process.

After the formation of the second electrode 300, a heat treatment, i.e., post metallization annealing (PMA), may be performed on the resulting structure. When PMA is performed after the formation of the second electrode 300, strain due to thermal expansion of the second electrode 300 may be induced, which may affect crystallization of the dielectric layer. As a non-limiting example, the PMA may be performed in a temperature range of about 400 to 700° C. in an N₂ atmosphere for a duration ranging from tens of seconds to tens of minutes. However, the specific PMA conditions may be varied. Further, the PMA may be performed, for example, by rapid thermal annealing (RTA).

FIG. 5D shows a structure of the final fabricated capacitor. The structure of FIG. 5D may correspond to the structure of FIG. 1.

Referring to FIG. 5D, the capacitor may include the first electrode 100, the second electrode 300 spaced apart from the first electrode 100, and a dielectric layer 200A disposed between the first electrode 100 and the second electrode 300 in the stacking direction. The dielectric layer 200A may include a first hafnium zirconium oxide layer region 217 disposed tangentially or adjacent to the first electrode 100, a second hafnium zirconium oxide layer region 237 disposed tangentially or adjacent to the second electrode 300, and an interlayer region 227 disposed between the first and second hafnium zirconium oxide layer regions 217 and 237 in the stacking direction. The first hafnium zirconium oxide layer region 217 may be a region doped with a first doping material. The second hafnium zirconium oxide layer region 237 may be a region doped with a second doping material different from the first doping material. The structure of FIG. 5D may correspond to the structure of FIG. 1, so that all of the features described with respect to FIG. 1 may apply to the structure of FIG. 5D.

The first and second hafnium zirconium oxide layer regions 217 and 237 may be regions formed by diffusion of doping materials into the dielectric layer from the first and second doping material layers 215 and 235 described in FIGS. 5B and 5C. Further, the interlayer region 227 may be a region formed by diffusion of a doping material into the dielectric layer from the intermediate material layer 225 described in FIGS. 5B and 5C. For illustrative convenience, FIGS. 5B and 5C illustrate the doping materials in an undiffused state, but diffusion of the doping materials may occur during the process of FIGS. 5B and 5C. In another embodiment, the interlayer region 227 may not be formed by diffusion of the doping material. For example, the interlayer region 227 may be formed as a separate layer of dielectric material, such as an oxide layer.

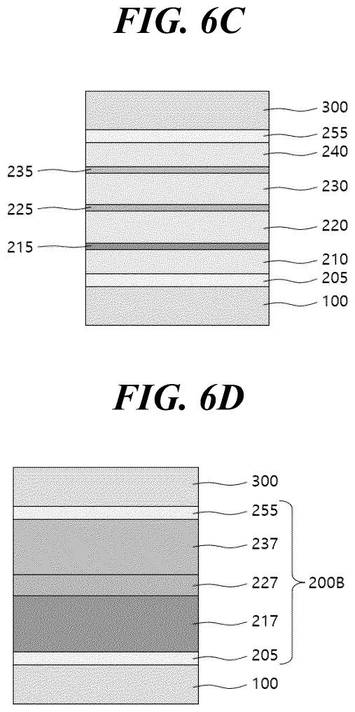

FIGS. 6A through 6D illustrate a method of manufacturing a capacitor according to another embodiment of the present disclosure.

Referring to FIG. 6A, a first electrode 100 may be provided. A first interfacial layer 205 may be formed on the first electrode 100. The first interfacial layer 205 may be formed, for example, by an ALD process. According to one embodiment, the first interfacial layer 205 may include an oxide containing at least one of In, Ga, Zn, Ti, Al, Sn, Y, Ca, Ba, or Sr, or InGaZnO. The first interfacial layer 205 may be an oxide layer. As a non-limiting example, the first interfacial layer 205 may be or may include an indium gallium zinc oxide layer. The indium gallium zinc oxide layer may be represented as an InGaZn oxide layer or an InGaZnO layer (or thin film). However, the specific material of the first interfacial layer 205 may be varied.

Referring to FIG. 6B, hafnium zirconium oxide layers 210, 220, 230, and 240 may be deposited on the first interfacial layer 205 by an ALD process. During the deposition of these hafnium zirconium oxide layers 210, 220, 230, and 240, a first doped material layer 215, an intermediate material layer 225, and a second doped material layer 235 may be formed therebetween. For example, the first hafnium zirconium oxide layer 210, the first doping material layer 215, the second hafnium zirconium oxide layer 220, the intermediate material layer 225, the third hafnium zirconium oxide layer 230, the second doping material layer 235, and the fourth hafnium zirconium oxide layer 240 may be formed in sequence on the first interfacial layer 205. This may be the same as, or similar to, the structure described in FIG. 5B.

Referring to FIG. 6C, a second interfacial layer 255 may be formed on the fourth hafnium zirconium oxide layer 240. The second interfacial layer 255 may be formed, for example, by an ALD process. According to one embodiment, the second interfacial layer 255 may include an oxide containing at least one of In, Ga, Zn, Ti, Al, Sn, Y, Ca, Ba, or Sr, or InGaZnO. The second interfacial layer 255 may be an oxide layer. As a non-limiting example, the second interfacial layer 255 may be, or may include, an indium gallium zinc oxide layer. The indium gallium zinc oxide layer may be represented as an InGaZn oxide layer or an InGaZnO layer (or thin film). However, the specific material of the second interfacial layer 255 may be varied. Subsequently, a second electrode 300 may be formed on the second interfacial layer 255.

After the formation of the second electrode 300, a heat treatment, i.e., post metallization annealing (PMA), may be performed on the resulting workpiece. The PMA conditions and related details may be described with reference to FIG. 5C.

FIG. 6D shows a structure of the final fabricated capacitor. The structure of FIG. 6D may correspond to the structure of FIG. 3.

Referring to FIG. 6D, the capacitor may include the first electrode 100, the second electrode 300 spaced apart from the first electrode 100, and a dielectric layer 200B disposed between the first electrode 100 and the second electrode 300 in the stacking direction. The dielectric layer 200B may include a first hafnium zirconium oxide layer region 217 disposed tangentially or adjacent to the first electrode 100, a second hafnium zirconium oxide layer region 237 disposed tangentially or adjacent to the second electrode 300, and an interlayer region 227 disposed between the first and second hafnium zirconium oxide layer regions 217 and 237 in the stacking direction. The dielectric layer 200B may further include at least one of a first interfacial layer 205 disposed between the first electrode 100 and the first hafnium zirconium oxide layer region 217 and a second interfacial layer 255 disposed between the second electrode 300 and the second hafnium zirconium oxide layer region 237. The first hafnium zirconium oxide layer region 217 may be a region doped with a first doping material. The second hafnium zirconium oxide layer region 237 may be a region doped with a second doping material different from the first doping material. The structure of FIG. 6D may correspond to the structure of FIG. 3, so that all of the features described with respect to FIG. 3 may apply to the structure of FIG. 6D.

The first and second hafnium zirconium oxide layer regions 217 and 237 may be formed by diffusion of doping materials into the dielectric layer from the first and second doping material layers 215 and 235 described in FIGS. 6B and 6C. Further, the interlayer region 227 may be formed by diffusion of a doping material into the dielectric layer from the intermediate material layer 225 described in FIGS. 6B and 6C. For illustrative convenience, FIGS. 6B and 6C illustrate the doping materials in an undiffused state, but diffusion of the doping materials may occur during the processes of FIGS. 6B and 6C. In another embodiment, the interlayer region 227 may not be formed using diffusion of the doping material. For example, the interlayer region 227 may be formed as a separate layer of dielectric material (e.g., an oxide layer).

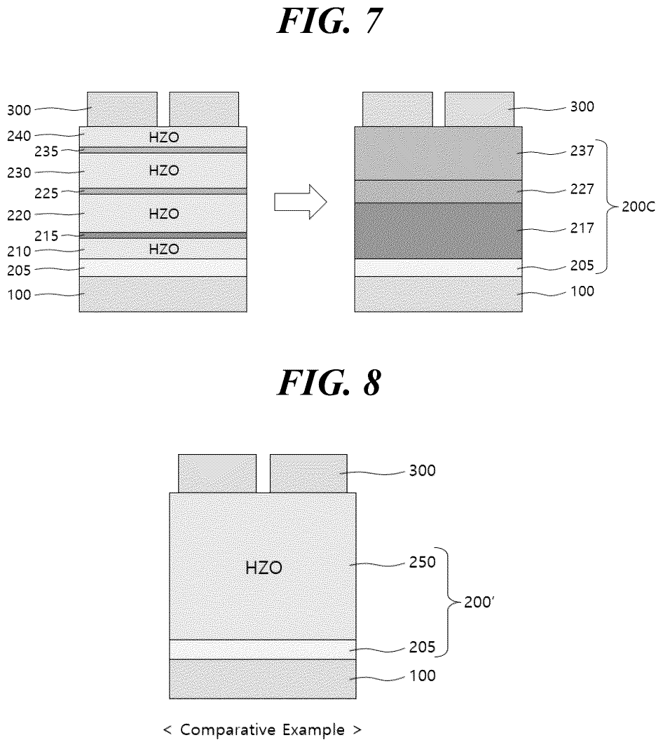

FIG. 7 illustrates a method of manufacturing a capacitor according to an embodiment of the present disclosure, as well as a capacitor manufactured by the method.

Referring to FIG. 7, a first interfacial layer 205, a first hafnium zirconium oxide layer 210, a first doping material layer 215, a second hafnium zirconium oxide layer 220, an intermediate material layer 225, a third hafnium zirconium oxide layer 230, a second doping material layer 235, and a fourth hafnium zirconium oxide layer 240 are sequentially deposited on a first electrode 100 using a method similar to the method described with reference to FIGS. 6A and 6B. After that, a second electrode 300 may be formed on the fourth hafnium zirconium oxide layer 240. The first electrode 100 may be a TiN electrode. The first interfacial layer 205 may be an InGaZnO layer. The first doping material layer 215 may be a Ta₂O₅ layer. The intermediate material layer 225 may be an Al₂O₃ layer. The second doping material layer 235 may be a La₂O₃ layer. The second electrode 300 may be a TiN electrode.

A thermal SiO₂ layer (e.g., about 400 nm thick) may be formed on a p-type Si substrate. A TiN electrode (e.g., about 20 nm thick) may then be formed as the first electrode 100 by an ALD process. An InGaZnO layer (e.g., about 0.7 nm thick) may be formed on the first electrode 100 as the first interfacial layer 205 by an ALD process. On the first interfacial layer 205, a hafnium zirconium oxide layer region (including layers 210, 215, and 220), including the first doping material layer 215, may be formed to a total thickness of about 2.8 nm. An Al₂O₃ layer (e.g., 1 ALD cycle) may be formed thereon as the intermediate material layer 225 by an ALD process. Subsequently, another hafnium zirconium oxide layer region (including layers 230, 235, and 240), including the second doping material layer 235, may be formed by an ALD process to a thickness of about 2.5 nm. On top of this, a TiN electrode (e.g., about 20 nm thick) may be formed as the second electrode 300 by the ALD process. Body patterning may be performed by a dry etch process, and the second electrode 300 may be patterned by a wet etching process. After that, a heat treatment for crystallization may be performed by an RTA method in a temperature range of about 400 to 700° C.

The source (precursor) for Hf may be a cyclopentadienyl (Cp)-based material (or compound), and the source (precursor) for Zr may also be a Cp-based material. A canister temperature of the sources in the formation of hafnium zirconium oxide layers (first to fourth hafnium zirconium oxide layers 210, 220, 230, and 240) may be about 90° C. The source (precursor) for Ta may be a Cp-based material, and a canister temperature during the formation of the Ta₂O₅ layer (first doping material layer 215) may be about 90° C. The source (precursor) for Al may be trimethylaluminum (TMA), and a canister temperature during the formation of the Al₂O₃ layer (intermediate material layer 225) may be maintained at room temperature. The source (precursor) for La may be an isopropylcyclopentadienyl (iPr-Cp) series material, and a canister temperature during the formation of the La₂O₃ layer (second doping material layer 235) may be about 160° C. Meanwhile, the source (precursor) for In may be trimethylindium (TMI), the source (precursor) for Ga may be trimethylgallium (TMG), and the source (precursor) for Zn may be diethylzinc (DEZ). A canister temperature for the source of In may be about 100° C., and a canister temperature for the source of Ga and the source of Zn may be maintained at room temperature. However, the source materials and process conditions described above are exemplary only and may be varied as needed.

The capacitor formed after the heat treatment may include the first electrode 100, the second electrode 300 spaced apart from the first electrode 100, and a dielectric layer 200C disposed between the first electrode 100 and the second electrode 300. The dielectric layer 200C may include a first hafnium zirconium oxide layer region 217 disposed tangentially or adjacent to the first electrode 100, a second hafnium zirconium oxide layer region 237 disposed tangentially or adjacent to the second electrode 300, and an interlayer region 227 disposed between the first and second hafnium zirconium oxide layer regions 217 and 237. Further, the dielectric layer 200C may include the first interfacial layer 205 disposed between the first electrode 100 and the first hafnium zirconium oxide layer region 217. The first hafnium zirconium oxide layer region 217 may be a region doped with a first doping material. The second hafnium zirconium oxide layer region 237 may be a region doped with a second doping material different from the first doping material.

FIG. 8 illustrates a cross-sectional view of a capacitor according to a comparative example.

Referring to FIG. 8, the comparative capacitor may include a first electrode 100, a second electrode 300 spaced apart from the first electrode 100, and a dielectric layer 200′ disposed between the first electrode 100 and the second electrode 300 in a stacking direction. The dielectric layer 200′ may include a first interfacial layer 205 and a hafnium zirconium oxide layer 250. The first interfacial layer 205 may be disposed between the first electrode 100 and the hafnium zirconium oxide layer 250. The hafnium zirconium oxide layer 250 is a HfₓZr₁₋ₓO₂ material layer (i.e., an H2O layer). The comparative capacitor was subjected to the same heat treatment conditions as the embodiment described in FIG. 7.

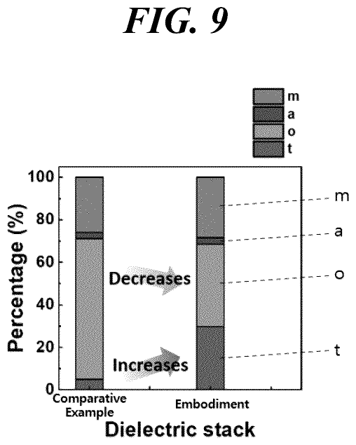

FIG. 9 is a graph showing results of measuring crystal structures of dielectric layers (or thin films) of capacitors according to an embodiment and a comparative example of the present disclosure. The embodiment of FIG. 9 is the same as the embodiment described in FIG. 7, and the comparative example of FIG. 9 is the same as the comparative example described in FIG. 8. In FIG. 9, t denotes a tetragonal phase, o denotes an orthorhombic phase, a denotes an amorphous phase, and m denotes a monoclinic phase.

Referring to FIG. 9, it may be seen that the tetragonal phase is less than 10% in the comparative example, while the tetragonal phase is more than 20% in the embodiment. Also, the orthorhombic phase is more than 60% in the comparative example, whereas the orthorhombic phase is reduced in the embodiment. The tetragonal phase in the dielectric layer of the embodiment may be greater than 20% and less than or equal to about 50%, as a non-limiting example. The orthorhombic phase in the dielectric layer of the embodiment may be greater than 10% and less than or equal to about 50%, as a non-limiting example.

When asymmetric structural doping is performed, such as in embodiments of the present disclosure, where the first and second hafnium zirconium oxide layer regions are doped with different materials, the stress within the dielectric layer may be enhanced, thereby inducing a change in the crystallinity of the dielectric layer. In this regard, the proportion of tetragonal phases in the dielectric layer may increase. As the proportion of tetragonal phases in the dielectric layer increases, the dielectric permittivity of the dielectric layer may increase, the equivalent oxide film thickness (EOT) may decrease, and the operational durability may be improved.

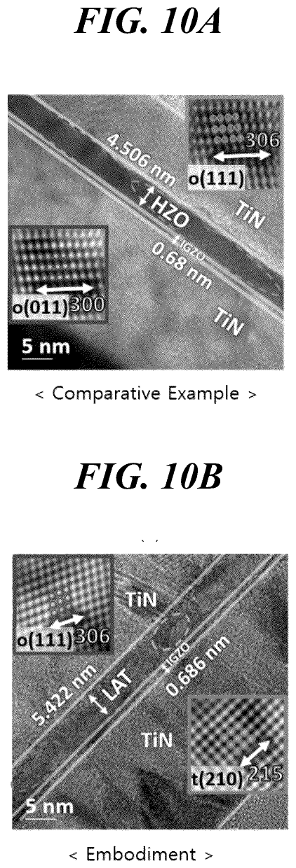

FIGS. 10A and 10B are transmission electron microscope (TEM) images of crystal structures of dielectric layers (or thin films) of capacitors according to an embodiment and a comparative example of the present disclosure. FIG. 10A illustrates a result for the comparative example, and FIG. 10B illustrates a result for the embodiment. The insets are high magnification images of an orthorhombic phase (i.e., o-phase) grain and a tetragonal phase (i.e., t-phase) grain. The embodiment of FIG. 10B is the same as the embodiment described in FIG. 7, and the comparative example of FIG. 10A is the same as the comparative example described in FIG. 8.

Referring to FIGS. 10A and 10B, a large amount of t-phase grains can be observed in the dielectric layer according to the embodiment, while the dielectric layer according to the comparative example is dominated by o-phase grains. The label ‘LAT’ in FIG. 10B indicates the dielectric layer having an asymmetric doping structure according to the embodiment.

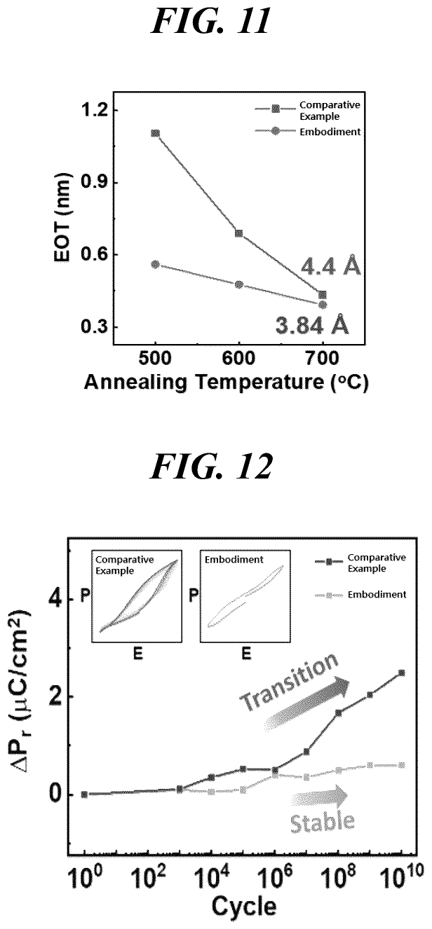

FIG. 11 is a graph showing results of measuring the change in equivalent oxide thickness (EOT) as a function of annealing (heat treatment) temperature conditions of dielectric layers according to an embodiment and a comparative example of the present disclosure. The embodiment of FIG. 11 is the same as the embodiment described in FIG. 7, and the comparative example of FIG. 11 is the same as the comparative example described in FIG. 8.

Referring to FIG. 11, it may be seen that an equivalent oxide thickness (EOT) of at least 0.384 nm may be obtained in the dielectric layer having an asymmetric doping structure formed according to the embodiment. Within the measured range, as the annealing (heat treatment) temperature increases, the equivalent oxide thickness (EOT) tends to decrease. In particular, at relatively low annealing temperature of about 500° C. to 600° C., the dielectric layer according to the embodiment may have a significantly reduced equivalent oxide thickness (EOT) compared to that of the dielectric layer according to the comparative example.

FIG. 12 is a graph showing the variation in ΔPᵣ (remanent polarization) with increasing operating cycles for dielectric layers according to an embodiment and a comparative example of the present disclosure. The insets illustrate P-E (polarization-electric field) characteristics of both the embodiment and the comparative example. The embodiment of FIG. 12 is the same as the embodiment described in FIG. 7, and the comparative example of FIG. 12 is the same as the comparative example described in FIG. 8.

Referring to FIG. 12, it may be seen that the dielectric layer according to the comparative example has a relatively large change in ΔPᵣ after about 10⁴ cycles, while the dielectric layer according to the embodiment has a stable ΔPᵣ characteristic after about 10⁴ cycles. This may indicate that the dielectric layer according to the embodiment has improved durability compared to that of the dielectric layer according to the comparative example.

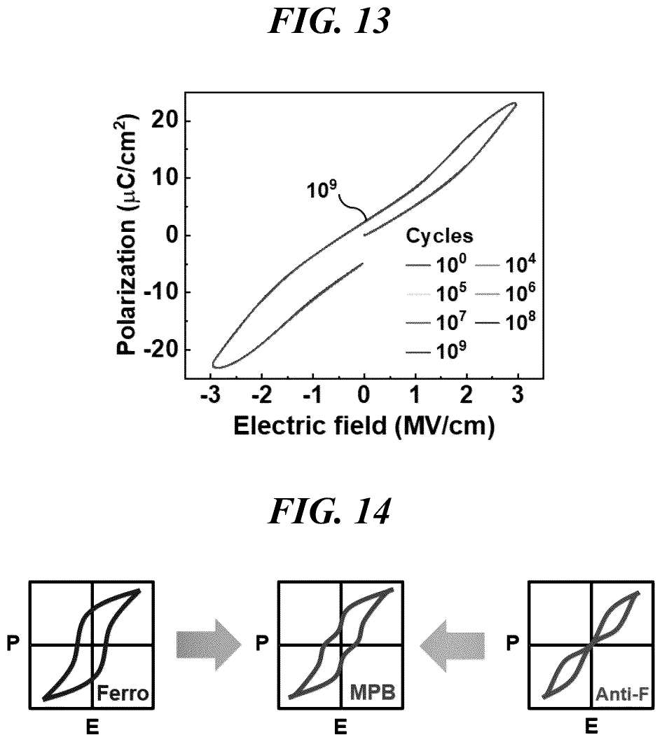

FIG. 13 is a graph showing P-E (polarization-electric field) characteristics of a dielectric layer according to an embodiment of the present disclosure.

Referring to FIG. 13, in the dielectric layer according to the embodiment, the anti- ferroelectric property may be enhanced to a certain extent as the proportion of tetragonal phases in the dielectric layer increases. When the anti-ferroelectric property becomes stronger as the proportion of tetragonal phases in the dielectric layer is secured to the certain extent, the dielectric layer may have a high dielectric constant near 0 V and may have improved durability (operational durability). Regardless of the number of operating cycles, the P-E characteristics remained nearly constant, indicating excellent stability.

FIG. 14 illustrates a morphotropic phase boundary (MPB) state that a dielectric layer of a capacitor according to an embodiment of the present disclosure may exhibit.

Referring to FIG. 14, in hafnium zirconium oxide, the tetragonal grains may exhibit semi-ferroelectric characteristics, while the orthorhombic grains may be ferroelectric. The dielectric layer may reach, or be in a state similar to, a phase transition region (also referred to as morphotropic phase boundary (MPB)) where both tetragonal and orthorhombic grains coexist. In this regard, the dielectric layer may have a high dielectric constant and excellent electrical properties.

The capacitor structure manufactured according to an embodiment of the present disclosure, such as the capacitor structures described in FIGS. 1 to 4, may be applied to various electronic or semiconductor devices. For example, the capacitor according to the embodiment of the present disclosure may be applied to a memory device that utilizes a capacitor as a data storage member. Here, the memory device may be a dynamic random access memory (DRAM). In order to apply the capacitor to a DRAM, it may be desirable to manufacture the capacitor by an ALD process. Since the capacitor according to the embodiment of the present disclosure may be fabricated by the ALD process, it may be easily applied to a DRAM. In FIGS. 1 to 4, the capacitor has a simple planar structure, but when applied as a capacitor for a DRAM, the capacitor may have various modified structures, such as a cylinder shape, a cup shape, etc.

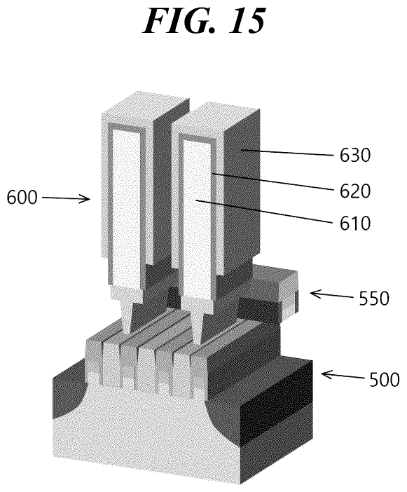

FIG. 15 illustrates an exemplary configuration of a DRAM device to which a capacitor according to an embodiment of the present disclosure is applied.

Referring to FIG. 15, the DRAM device may include a cell transistor 500 and a capacitor 600 electrically coupled thereto. The capacitor 600 may include a first electrode 610, a second electrode 630, and a dielectric layer 620 disposed between the first and second electrodes 610 and 630. The first electrode 610 may be a lower electrode, and the second electrode 630 may be a higher electrode. The dielectric layer 620 may have an asymmetric doping structure. In addition, the dielectric layer 620 may have any of the characteristics of the afore-mentioned embodiments. However, the structure of the capacitor 600 shown in FIG. 15 is exemplary only and may be varied. The capacitors according to the embodiments of the present disclosure may be applied to any capacitor structure used in conventional DRAMs. When the capacitor according to the embodiment of the present disclosure is applied to a DRAM, it may be advantageous in improving integration and improving performance. Furthermore, the capacitor according to the embodiment of the present disclosure may be applied to other memory devices other than DRAMs and other electronic or semiconductor devices. In FIG. 15, undescribed reference numeral 550 indicates a bit line.

A method of fabricating an electronic device (e.g., a memory device) according to embodiments of the present disclosure may include a method of fabricating a capacitor according to any of the foregoing embodiments.

According to embodiments of the disclosure described above, it is possible to implement a capacitor including a dielectric layer that may have a thin equivalent oxide thickness (EOT) with a high dielectric constant and improved leakage current characteristics. Further, according to embodiments of the present disclosure, a capacitor may be implemented in which the crystallinity of the dielectric layer is controlled to enhance the dielectric constant and improve durability. Furthermore, according to embodiments of the present disclosure, a capacitor including a hafnium zirconium oxide layer may be implemented, which may reduce leakage current and improve durability and reliability. In particular, according to embodiments of the present disclosure, by varying the doping materials in the lower and upper regions of the dielectric layer to induce a change in the crystallinity of the entire dielectric layer, the dielectric constant and durability may be improved, and a reduced equivalent oxide thickness (EOT) may be obtained. According to embodiments of the present disclosure, a high dielectric constant and excellent electrical properties may be obtained by creating a phase transition region, such as a morphotropic phase boundary (MPB) or similar state, in the hafnium zirconium oxide in which anti-ferroelectric tetragonal grains coexist with ferroelectric orthorhombic grains. Capacitors incorporating this structure may be usefully applied to electronic devices, for example, memory devices such as DRAMs, thereby improving the integration and performance of memory devices.

This description discloses preferred embodiments of the present disclosure, and although certain terms are used, they are used in a general sense only to facilitate the description and understanding of the disclosure and are not intended to limit the scope of the disclosure. In addition to the embodiments disclosed herein, other modifications based on the technical ideas of the present disclosure will be apparent to those of ordinary skill in the art to which the present disclosure belongs. One of ordinary skill in the art will recognize that the capacitors, methods of making capacitors, electronic devices comprising capacitors, and methods of making electronic devices according to the embodiments described with reference to FIGS. 1 through 7 and FIGS. 9 through 15 may be subject to various substitutions, changes, and modifications without departing from the technical ideas of the present disclosure. As a specific example, doping materials for the hafnium zirconium oxide may include Ta, Ti, La, and Y, as well as other doping materials such as Ca, Dy, and the like. The scope of the disclosure is therefore not to be limited by the embodiments described, but rather by the technical ideas recited in the patent claims.

What is claimed is:

1. A capacitor, comprising:
a first electrode;
a second electrode spaced apart from the first electrode; and
a dielectric layer disposed between the first electrode and the second electrode,
wherein the dielectric layer comprises:
a first hafnium zirconium oxide layer region in contact with or adjacent to the first electrode, the first hafnium zirconium oxide layer region being doped with a first doping material;
a second hafnium zirconium oxide layer region in contact with or adjacent to the second electrode, the second hafnium zirconium oxide layer region doped with a second doping material different from the first doping material; and
an interlayer region disposed between the first and second hafnium zirconium oxide layer regions.

2. The capacitor of claim 1, wherein the first doping material comprises an element that induces compressive stress in the first hafnium zirconium oxide layer region, and
the second doping material comprises an element that induces tensile stress in the second hafnium zirconium oxide layer region.

3. The capacitor of claim 1, wherein the first doping material comprises an element having a smaller atomic size than Hf and Zr, and
the second doping material comprises an element having a larger atomic size than Hf and Zr.

4. The capacitor of claim 1, wherein the first doping material comprises Ta, Ti, or a combination thereof, and
the second doping material comprises La, Y, or a combination thereof.

5. The capacitor of claim 1, wherein a proportion of tetragonal phases in the dielectric layer is equal to or greater than 20%.

6. The capacitor of claim 1, wherein the interlayer region comprises an oxide containing at least one element selected from the group consisting of Al, Y, La, Ta, Ca, Si, Zr, Hf, and Ti.

7. The capacitor of claim 1, further comprising:
a first interfacial layer disposed between the first electrode and the first hafnium zirconium oxide layer region; and
a second interfacial layer disposed between the second electrode and the second hafnium zirconium oxide layer region.

8. The capacitor of claim 7, wherein at least one of the first and second interfacial layers comprises an oxide containing at least one element selected from the group consisting of In, Ga, Zn, Ti, Al, Sn, Y, Ca, Ba, and Sr, or comprises InGaZnO.

9. A memory device comprising the capacitor of claim 1 as a data storage member.

10. The memory device of claim 9, wherein the memory device comprises a dynamic random access memory (DRAM).

11. A capacitor, comprising:
a first electrode;
a second electrode spaced apart from the first electrode; and
a dielectric layer disposed between the first electrode and the second electrode,
wherein the dielectric layer comprises:
a first hafnium zirconium oxide layer region in contact with or adjacent to the first electrode, the first hafnium zirconium oxide layer region having a compressively strained structure;
a second hafnium zirconium oxide layer region in contact with or adjacent to the second electrode, the second hafnium zirconium oxide layer region having a tensile strained structure; and
an interlayer region disposed between the first and second hafnium zirconium oxide layer regions.

12. A method of manufacturing a capacitor, the method comprising:
preparing a first electrode;
forming a dielectric layer over the first electrode;
forming a second electrode over the dielectric layer; and
heat treating a laminated structure comprising the first electrode, the dielectric layer, and the second electrode,
wherein the dielectric layer comprises a first hafnium zirconium oxide layer region in contact with or adjacent to the first electrode and doped with a first doping material, a second hafnium zirconium oxide layer region in contact with or adjacent to the second electrode and doped with a second doping material different from the first doping material, and an interlayer region disposed between the first and second hafnium zirconium oxide layer regions.

13. The method of claim 12, wherein the dielectric layer is formed using an atomic layer deposition (ALD) process.

14. The method of claim 12, wherein the first doping material comprises an element that induces compressive stress in the first hafnium zirconium oxide layer region, and
the second doping material comprises an element that induces tensile stress in the second hafnium zirconium oxide layer.

15. The method of claim 12, wherein the first doping material comprises an element having a smaller atomic size than Hf and Zr, and
the second doping material comprises an element having a larger atomic size than Hf and Zr.

16. The method of claim 12, wherein the first doping material comprises Ta, Ti, or a combination thereof, and
the second doping material comprises La, Y, or a combination thereof.

17. The method of claim 12, wherein a proportion of tetragonal phases in the dielectric layer is equal to or greater than 20%.

18. The method of claim 12, wherein the interlayer region comprises an oxide containing at least one element selected from the group consisting of Al, Y, La, Ta, Ca, Si, Zr, Hf, and Ti.

19. The method of claim 12, further comprising:
at least one of:
forming a first interfacial layer disposed between the first electrode and the first hafnium zirconium oxide layer region; and
forming a second interfacial layer disposed between the second electrode and the second hafnium zirconium oxide layer region.

20. The method of claim 19, wherein at least one of the first and second interfacial layers comprises an oxide containing at least one element selected from the group consisting of In, Ga, Zn, Ti, Al, Sn, Y, Ca, Ba, and Sr, or comprises InGaZnO.

21. The method of claim 12, wherein the heat treating is performed at a temperature of 400° C. to 700° C.
